(19) United States
(12) Patent Application Publication
(10) Pub. No.: US 2017/0117425 A1
(43) Pub. Date: Apr. 27, 2017

(54) METHOD FOR MANUFACTURING A SOLAR CELL MODULE AND SOLAR CELL MODULE

(71) Applicant: SOLARWORLD AG, Bonn (DE)

(72) Inventors: Frank ASBECK, Bonn (DE); Markus HUND, Euskirchen (DE); Harald HAHN, Dresden (DE); Matthias GEORGI, Dresden (DE)

(73) Assignee: SOLARWORLD AG, Bonn (DE)

(21) Appl. No.: 15/291,457

(22) Filed: Oct. 12, 2016

(30) Foreign Application Priority Data
Oct. 23, 2015 (DE) 102015220799.4

(51) Int. Cl. H01L 31/0475; H01L 31/049; H01L 31/054

(52) U.S. Cl. CPC H01L 31/0475; H01L 31/0547; H01L 31/049

(57) ABSTRACT

The present invention relates to a method for manufacturing a solar cell module by the steps of: providing at least two bifacial solar cells; adjoining arrangement of the solar cells, wherein a gap is provided between the solar cells; providing a diffuse reflector in the gap area. The present invention also relates to such a solar cell module, wherein the diffuse reflector is disposed and configured such that it diffusely reflects the incident light and a portion of the diffusely reflected lights strikes on the solar cell through total reflection at the front boundary layer of the solar cell module.

### FIELD OF INVENTION

The present invention relates to a method for manufacturing a method for manufacturing a solar cell module and a solar cell module.

### TECHNICAL BACKGROUND

Solar cell modules, also referred to as photovoltaic modules (PV-Modules), generally have several solar cells. A special type of solar cell module has so-called bifacial solar cells. Bifacial solar cells can absorb light on the front as well as on the rear-side and convert into electrical energy. Therefore, even reflected or indirect light on the rear-side of the solar cells can be converted in such solar cells and thereby the efficiency of the solar cells is increased.

Solar cell modules with bifacial solar cells are referred to as bifacial solar cell modules. One of the Applicant's known bifacial solar cell module has a transparent front and rear-side. Therefore, the light striking in a gap of two adjacent solar cells passes through the solar cell module and is lost for power generation.

### SUMMARY OF THE INVENTION

In this context, the object underlying the present invention is to specify an improved method for manufacturing a solar cell module and an improved solar cell module.

In accordance with the invention, this object is achieved by a method with the features of the patent claim 1 and/or by a solar cell module with the features of the patent claim 16.

Accordingly, it is provided:

a method for manufacturing a solar cell module with the steps: providing at least two bifacial solar cells; arranging the solar cells adjacently, wherein there is a gap provided between the solar cells; providing a diffuse reflector in the gap area.

A solar cell module, particularly manufactured according to a method in accordance with the invention, with at least two adjoining bifacial solar cells, wherein there a gap provided between the solar cells and a diffuser reflector is arranged and configured in the gap, such that it diffusely reflects the light incident in the gap and a portion of the diffusely reflected light strikes on the solar cells by total reflection on the front boundary layer of the solar cell module.

The guiding principle of the present invention is that a light returned from a diffuse reflector strikes highly inclined on the front-side of the solar module to the boundary layer with air and therefore, is totally reflected. Therefore, the front-side mainly describes the side exposed to the direct sunlight.

Therefore, the idea underlying the present invention is to arrange a diffuse reflector in the otherwise transparent gap of bifacial solar cells in a bifacial solar cell module with transparent front-side and rear-side. Thus, the light striking in the gap area can again strike and be used on the solar cells. Thus, advantageously an additional light capture is realized and the efficiency of the solar module is increased.

The diffuse reflector is preferably disposed on the side of the bifacial solar cell facing the rear-side of the solar cell module. Even an arrangement of the reflector at the same level as the solar cells could be realized.

Thus, an arrangement means an arrangement of the diffuse reflector in the gap area, in which light incident in the gap from the front-side of the solar cell module strikes on the reflector. Preferably, therefore, the reflector does not extend over the entire rear-side of the bifacial solar cell, but largely leaves this out, particularly on the sections of the solar cells away from the gap.

Advantageous configurations and improvements result from the further subordinate claims and from the description with reference to the figures of the drawing. According to an embodiment, the reflector is provided as a stand-alone component. According to the invention, the reflector provided as a stand-alone component is added before or after lamination of the solar cell module.

Advantageously, the reflector can thus be positioned particularly easily and quickly.

According to a preferred configuration, the reflector is provided as a flat unstructured surface element. Preferably, the reflector is white. Thus, a diffuse reflector is advantageously enabled very easily, particularly according to the Lambert's Law. Lambert's Law describes, how the radiation intensity decreases with lower angle of reflected beam due to the perspective effect. If a surface follows the Lambert's Law and the radiation density of the surface is constant, there is a circular distribution of the radiation intensity. Thus, a large portion of the light is obliquely incident. If the obliquely incident light strikes on the front boundary layer of the solar cell with the surrounding air at an adequate angle of incidence, it is totally reflected and thus returned in the direction of the solar cells.

According to an embodiment, the reflector is disposed directly on the rear-side of the solar cell before embedding the solar cell. Subsequently, the reflector is preferably embedded located together with the solar cells directly on the rear-side of the solar cells. Advantageously, the reflector can thus be safely positioned in a simple manner and without retaining means for subsequent embedding or lamination, preferably between two layers of Ethylene vinyl acetate (EVA). According to an improvement, the reflector is attached on the rear-side of the solar cells in the form of an adhesive strip or an adhesive film. Thus, the reflector is affixed on the solar cell. Advantageously, the reflector is thus self-adhesive and can be applied in a simple manner in the form, in which the gaps in the solar cell module are arranged, i.e. particularly linear or grid-shaped. In case of an adhesive film, this can be accordingly prefabricated, particularly cut-out or stamped. Further, the cutting of the adhesive film matching the shape of the gap can also be realized during or after placing and the corresponding removal of the recessed areas.

According to an embodiment, the solar cells are laminated between a front-side surface layer and a back cover, wherein the reflector is attached before lamination on an inner side of the back cover. Preferably, the front-side surface layer and the back cover are transparent. For example, these are designed of glass or a transparent film.

According to another embodiment, the solar cells are disposed between two plastic layers, wherein the reflector is provided in the form of a prior coloring in a rear-side plastic coating or in the form of an imprint on the rear-side plastic coating. Subsequently, the solar cells along with the reflector are embedded in the material of the plastic coatings by lamination. Preferably, the plastic coatings contain Ethylene vinyl acetate (EVA). Advantageously, the reflector can thus be positioned together with the plastic coatings and no additional positioning step is necessary for the reflector itself.

According to another embodiment, the reflector is attached to the rear-side of a back cover of the solar cell module. Particularly advantageously, the reflector can thus also be positioned subsequent to the lamination. Thus, the reflector cannot inadvertently slip during lamination.

According to an advantageous improvement, the back cover is provided as a rear-side glass. Thus, a particularly resistant surface of the back cover is advantageously provided with permanent high transparency, which is beneficial for capturing scattered light on the rear-side.

According to an embodiment, the reflector is attached on the back cover in the form of an imprint, an adhesive strip or an adhesive film. Thus, different designs of the reflectors are advantageously enabled to flexibly match the solar cells arrangement. However, the reflector can thereby be attached very quickly and easily.

According to an embodiment, the reflector is arranged or configured linear or grid-shaped. This can be realized in any configuration of the reflector. In particular, the lines or grid-lines are arranged such that all solar cells are thus bordered in the gap area of an adjacent solar cell. The border of the solar cells in the gap area of an adjacent frame of the solar cell module can also be realized.

According to an embodiment, the reflector is attached to the rear-side of a rear-side glass of the solar cell module, wherein the rear-side glass is at least partially surface treated for applying a reflector. Advantageously, the reflector is thus configured integral with the rear-side glass and no additional component is required. In addition, a durable reflector is thus made.

According to an improvement, the rear-side glass is vaporized with a metal for applying the reflector.

According to another configuration, the rear-side glass is etched or irradiated for applying the reflector. The etching can be realized for example by means of hydrofluoric acid (HF). The irradiation can be done for example by water or a suspension. Further, the grinding of the reflector could also be realized. Thus, the diffuse reflector can be advantageously realized in the material of the rear-side glass itself, particularly by making a rough surface, whereby this is configured fully integral with the rear-side glass. The application of the reflector in this case means the processing of the rear-side glass itself.

According to an improvement, a grid-shaped structure of the reflector is applied on the rear-side glass during the surface treatment by means of a grid-mask. In another configuration, the grid-shaped structure can also be applied without a mask by a controlled nozzle. Advantageously, the grid-structure can thus be applied in a simple manner only

after laminating the solar cell module. Therefore, a possible blurring of the solar cell-arrays during lamination can be compensated further advantageously. Accordingly, before the surface treatment, a step of positional control and an alignment of the laminate can be provided.

According to an embodiment of a solar cell module, the diffuse reflector is configured as a flat unstructured surface element.

According to another embodiment, the diffuse reflector includes an adhesive strip or an adhesive film with a pigment coating and with an adhesive layer. The pigment coating could preferably be white pigments, for example pigments which contain Titanium oxide, Calcium carbonate or Barium sulfate. The pigments can be bonded for example in an organic matrix. Likewise, it could be a white filled adhesive, for example Silicon or Epoxy based adhesive. Accordingly, the adhesive layer and the pigment coating can also form a common layer. The adhesive tape or the adhesive film contains for example Polyethylene terephthalate (PET) or a Fluoropolymer as carrier.

According to an embodiment, the diffuse reflector includes an imprint or an adhesive or a baking varnish, which contains white particle. White particles could be for example, Titanium oxide, Calcium carbonate or Barium sulfate. This can be present bonded in an organic matrix or in the form of a white filled adhesive, for example Silicon or Epoxy based adhesive.

In another embodiment, the diffuse reflector is formed with a partially surface treated rear-side glass of the solar cell module. The coating, for example a metal vaporized coating, etching, irradiation, or surface grinding are suitable as surface treatment. For example, hydrofluoric acid can be used for etching; water or a suspension can be used for irradiation.

In all configurations, the material for embedding or lamination could be Ethylene vinyl acetate (EVA). In particular, the solar cells are inlaid for embedding between two EVA layers, which are disposed between the front-side and the back cover. Subsequently, the lamination is done. Lamination means a thermal, material binding joining process without any auxiliary materials. Here, the material of the plastic coating is melted. In case of EVA, this is done at temperatures of about 150° C. Therefore, EVA is crystal clear and three-dimensionally cross-linked. After cooling down, there is such a durable bond, which protects the solar cells from environmental effects.

The above configurations and improvements can be combined, where appropriate, in any required manner. In particular, all features of the method for manufacturing a solar cell module also describe the features of the solar cell module do manufactured, and vice-versa. Further possible configurations, improvements and implementations of the invention also include the combinations of the features of the invention, not explicitly mentioned described above or described in the following with reference to the exemplary embodiments. In particular, the skilled person will therefore also add individual aspects as improvements or additions to the respective basic form of the present invention.

### SUMMARY OF THE DRAWING

The present invention is described in more details in the following with the help of exemplary embodiments specified in schematic figures of the drawings. Therefore, it is shown that:

FIG. 1 shows a schematic cross-sectional representation of a solar cell module according to a first embodiment;

FIG. 2 shows a schematic cross-sectional representation of a solar cell module according to a second embodiment;

FIG. 3 shows a schematic cross-sectional representation of a solar cell module according to a third embodiment;

FIG. 4 shows a schematic cross-sectional representation of a solar cell module according to a fourth embodiment;

FIG. 5 shows a schematic representation of a top-view on a section of the solar cell module.

The accompanying figures of the drawing shall show another understanding of the embodiments of the invention. These illustrate the embodiments and are used in connection with the description of the explanation of the principles and concepts of the invention. Other embodiments and many of the advantages mentioned, result in view of the drawings. The elements of the drawings are not necessarily shown to scale with respect to each other.

In the figures of the drawing, the same, functionally similar and similarly functioning elements, features and components—unless otherwise specified—are respectively provided with the same reference numerals.

### DESCRIPTION OF EMBODIMENTS

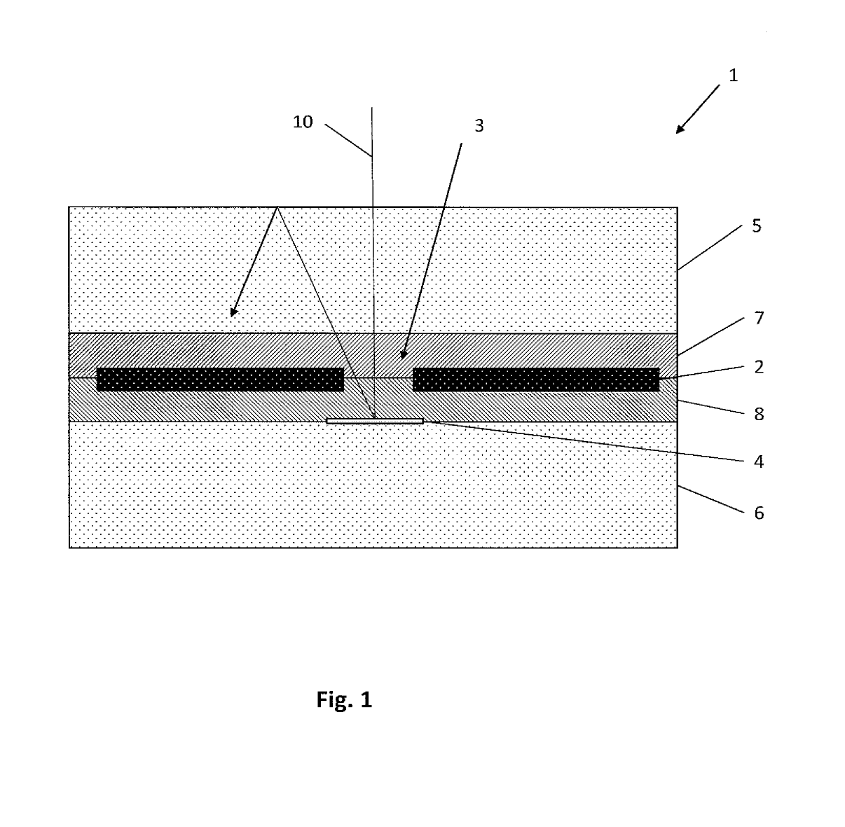

FIG. 1 shows a schematic cross-sectional representation of a solar cell module 1 according to a first embodiment.

The solar cell module 1 has two adjoining solar cells 2 in the depicted section of the section plane. A gap 3 is provided between the two solar cells 2. The number of two solar cells is purely as an example. Any higher number of solar cells 2 can also be provided, wherein a gap is respectively provided between two adjoining solar cells. Therefore, the depicted arrangement can safely proceed laterally with further solar cells in the same manner.

Both the solar cells 2 are embedded in the material of two plastic layers 7, 8. Thus, preferably it could be EVA coatings.

Further, a front surface layer 5 and back cover 6 close the solar cell module 1 from front and rear, i.e. in the section plane represented upwards and downwards. Therefore, it could

respectively be a glass layer or a film layer. Further, only the front surface 5 can also be provided as a glass layer and the back cover 6 as a film layer, or vice-versa.

In the present exemplary embodiment, a diffuser reflector 4 is disposed in the gap area 3 between a rear-side EVA plate 8 and a back cover 6.

For example, the reflector could be an adhesive tape provided with a white pigment coating. Further, the reflector can also be provided in the form of a coloring in the rear-side plastic layer or in the form of an imprint on the rear-side plastic layer.

For manufacturing the solar cell module 1, the solar cells 2 are disposed between the plastic layers 7, 8 with the predefined gap 3.

The reflector 4 is attached on the back cover 6 in case of an adhesive band positioned such that in an assembled state, the reflector 4 is disposed in the gap area 3 between the solar cells 2.

In case of a coloring in the rear-side plastic layer 8 or an imprint on the rear-side plastic layer 8, the solar cells and the plastic layer are accordingly positioned with each other, so that in an assembled state, the reflector 4 is disposed in the gap area 3 between the solar cells 2.

Subsequently, the solar cell module 1 is laminated. Therefore, the front surface layer 5 and the back cover 6 are joined to each other via the material of the plastic layers 7, 8, so that the solar cells 2 are embedded therebetween. In case of EVA, this is done at temperatures of about 150° C. Therefore, EVA is initially fluid and crystal clear and then cross-linked three-dimensionally.

After cooling down, there is a durable bond. Thus, the reflector 4, the front surface layer 5 and the back cover 6 are firmly joined with the material of the plastic layers 7, 8.

In the solar cell module 1 shown, light striking in the gap 3 from the front surface on the diffuse reflector 4 is diffusely reflected and largely strikes obliquely on the boundary layer of the front surface layer 5 of the solar module 1 with the surrounding air. Therefore, a higher portion of the diffusely reflected light is totally reflected on this boundary layer and can thus be used in the solar cell module 1. A corresponding beam path is marked by an arrow 10 as an example.

Therefore, the front-side represents a side facing the direct sunlight.

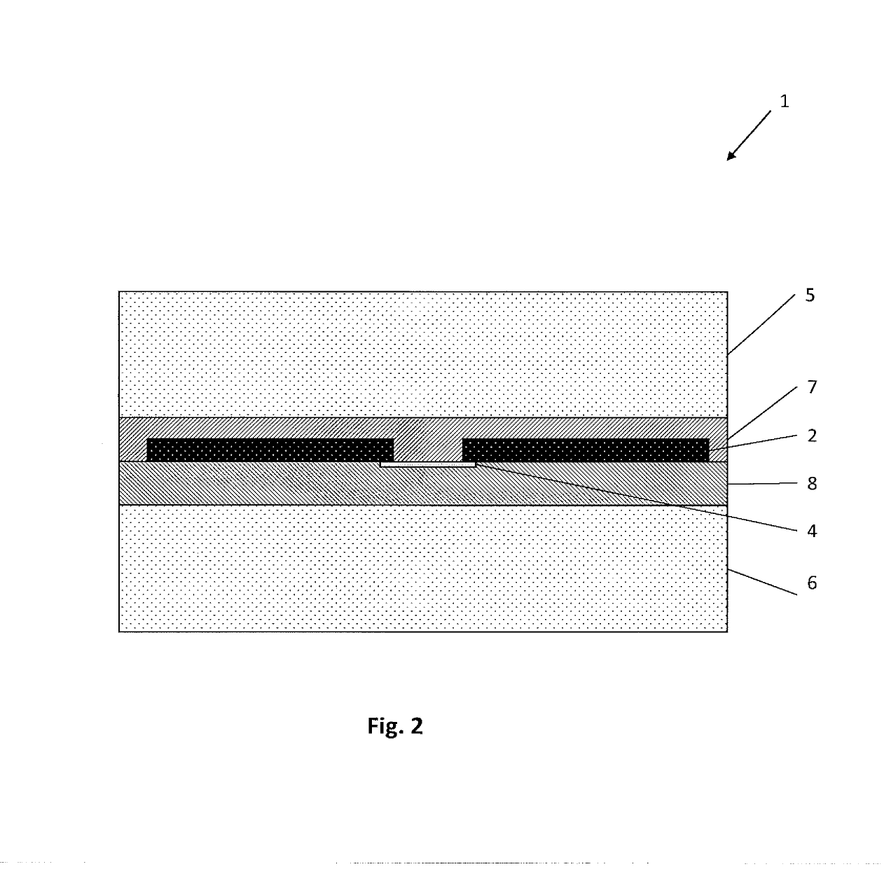

FIG. 2 shows a schematic cross-sectional representation of a solar cell module 1 according to a second embodiment.

In contrast to the first embodiment, here, the diffuse reflector 4 is disposed directly on a rear-side of the solar cells 2. Preferably, it could thus also be an adhesive tape or an adhesive film with white pigment coating.

During the manufacture, the reflector 4 is glued on the rear-side of the solar cells 2, before lamination.

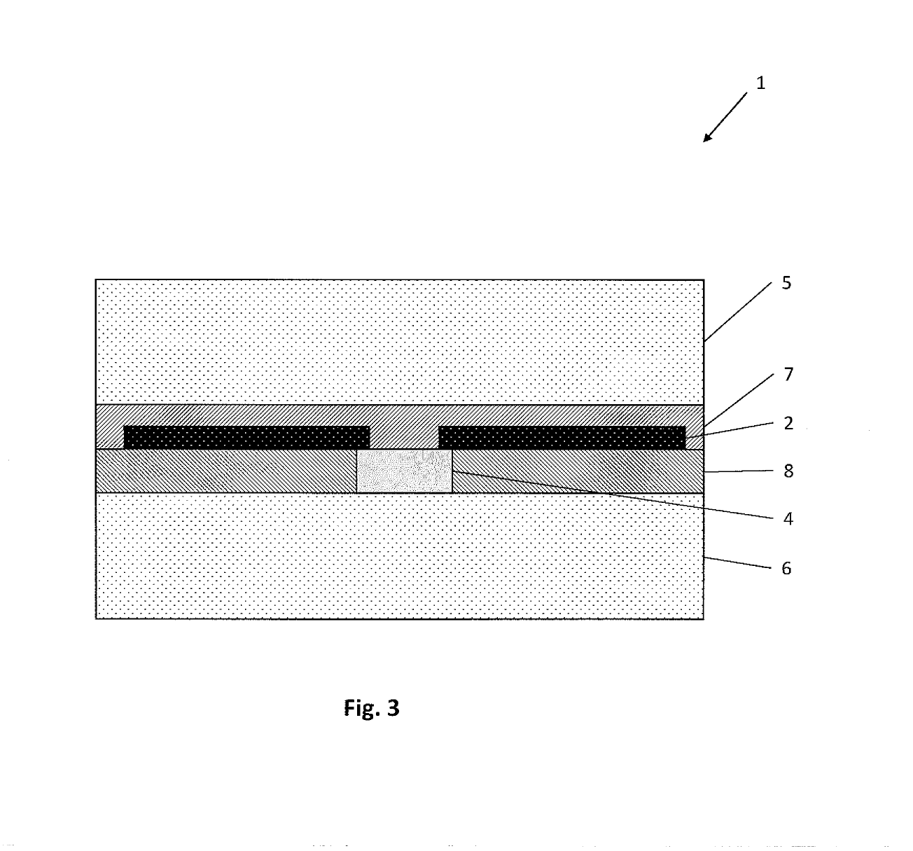

FIG. 3 shows a schematic cross-sectional representation of a solar cell module 1 according to a third embodiment.

In this embodiment, the reflector 4 is configured as a rectangular body with a thickness spanning the distance between the back cover 6 and the solar cells 2. Thus, simultaneously it is flush with the back cover 6 and the solar cells 2.

Therefore, the reflector 4 can also be used here additionally as positioning aid for the solar cells 2, during lamination.

An additional stage could be provided on the reflector 4 for exact positioning of the solar cells 2.

For manufacturing, the lower plastic layer 8 is separately provided and the reflector 4 is inlaid therebetween. Subsequently, the solar cells 2 is disposed thereupon and the front plastic layer 7 is provided thereon. During lamination, the reflector 4 can then support the solar cells 2 on the rear-side thereof, so that these remain at the level of the reflector 4 in spite of a pressure applied during lamination.

Obviously, several reflectors 4 supporting the solar cells can also be respectively provided on the edge of the solar cells 2, particularly surrounding the solar cells 2.

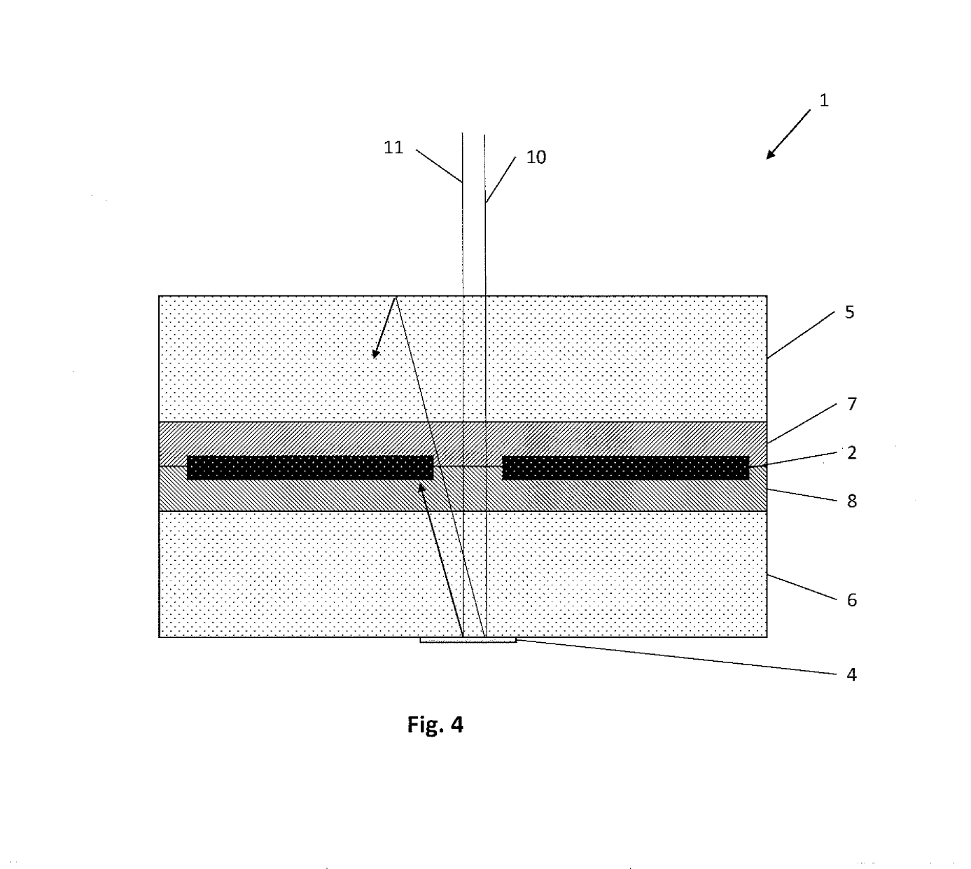

FIG. 4 shows a schematic cross-sectional representation of a solar cell module 1 according to a fourth embodiment.

Here, the reflector 4 is provided on the rear-side of the back cover 6. Depending on the distance from the solar cells 2, a portion of the diffusely reflected light can also directly strike on the rear-side of the solar cells 2 in this arrangement. This beam path is marked with an arrow 11 as an example. Another portion of the diffusely reflected light is returned through the gap 3 to the front-side, analogous to the beam path marked in FIG. 1 and can be partially returned there through total reflection to the boundary layer with the air. This beam path is likewise marked here with an arrow 10 as an example.

In the embodiment shown here, the reflector 4 is preferably attached only after lamination. For example, it can be imprinted on the back cover 6 subsequently. An adhesive tape strip can also be applied outside the rear-side as reflector 4.

So long as the back cover 6 is a rear-side glass, the reflector 4 is applied by means of a surface treatment of the rear-side glass 6, for example by means of vaporization, etching, irradiation or grinding.

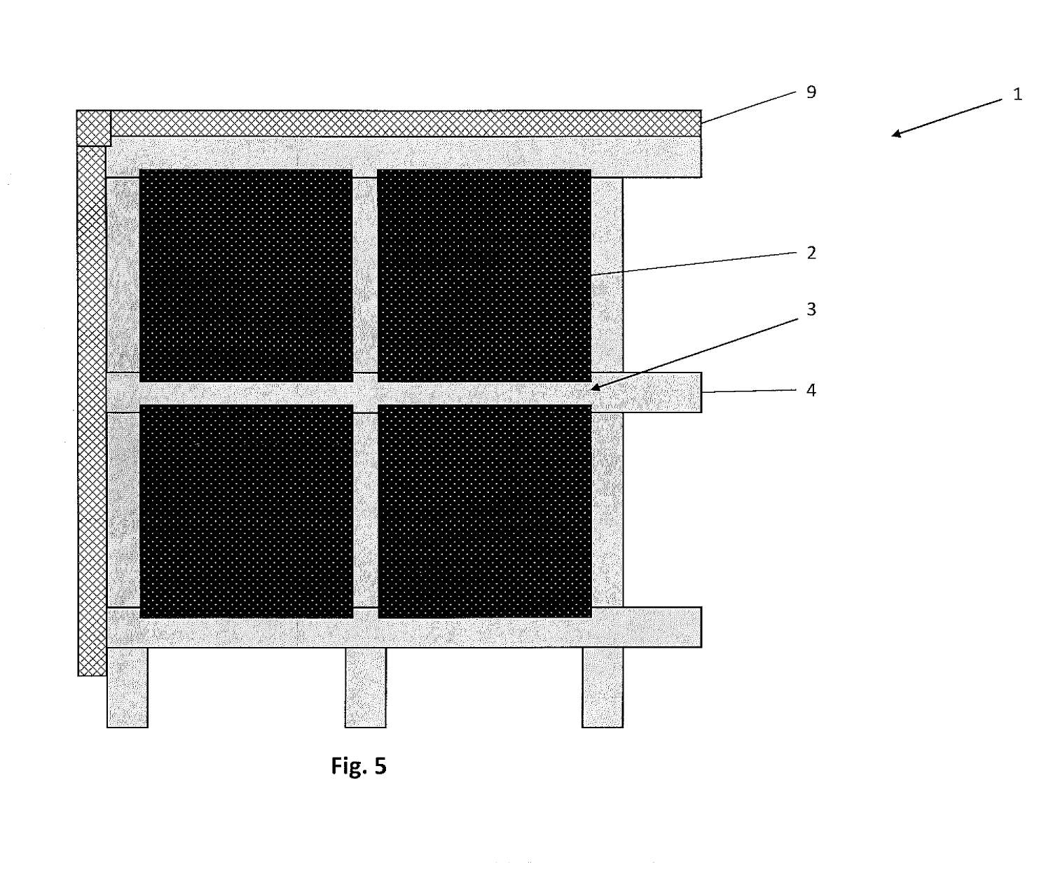

FIG. 5 shows a schematic representation of a top-view at a section of the solar cell module 1.

The solar cell module 1 is represented in a corner segment and proceeds downwards and rightwards in the representation, not shown.

The solar cell module 1 has a surrounding frame 9, which is likewise represented only in the corner segment.

In the corner segment, four solar cells 2 are uniformly disposed and mutually spaced apart with the same gap 3 respectively. The scheme of this arrangement proceeds preferably over the entire solar cell module.

Further, the solar cells 2 are also disposed having a gap from the frame 9. A diffuser reflector 4 is respectively provided in all the gaps, which is respectively configured as an adhesive tape in this embodiment.

The solar cells 2 and the frame 9 are configured rectangular and the solar cells 2 are disposed uniformly and having the same size. Accordingly, the reflectors 4 intersect regularly, so that there is a grid-shaped arrangement.

Alternative to a grid-shaped arranged adhesive tapes, a correspondingly cut-off adhesive film or a correspondingly applied imprint can also be provided.

The reflector 4 has a pigment coating with white pigments, for example containing Titanium oxide, Calcium carbonate or Barium sulfate. The pigments can be bonded, for example in an organic matrix. Likewise, it could be a white filled adhesive, for example based on Silicon or Epoxy. Accordingly, the adhesive layer and the pigment coating can also form a common layer.

Although, the present invention was completely described above with the help of preferred exemplary embodiments, it is not restricted to these, but can be modified in many ways.

In particular, even different configuration and/or arrangements of the reflector 4 can be combined in a solar cell module 1.

Further, intersecting reflectors 4 can be configured mutually integrally or overlapping each other. It is also possible that one of the mutually intersecting reflectors 4 is interrupted at the intersection, for example for insulation, if it involves a conductive material.

### LIST OF REFERENCE NUMERALS

1 Solar cell module
2 Solar cell
3 Clearance
4 Reflector
5 Front surface layer
6 Back cover
7 Plastic layer
8 Plastic layer
9 Frame
10, 11 Beam path

1. Method for manufacturing a solar cell module by the following steps:
Adjacently arranging at least two bifacial solar cells, wherein a gap is provided between the solar cells;
arranging a diffuse reflector with flat surface in the gap area.

2. Method according to claim 1, characterized in that the reflector is attached on the rear-side of the solar cells in the form of an adhesive tape or an adhesive film, before embedding the solar cells.

3. Method according to claim 1, characterized in that the solar cells are laminated between a front surface layer and a back cover, wherein the reflector is attached to an inner side of the back cover, before lamination.

4. Method according to claim 1, characterized in that the solar cells are disposed between two plastic layers, wherein the reflector is provided beforehand in the form of a coloring in the rear-side plastic layer or in the form of an imprint on the rear-side plastic layer and wherein the solar cells along with the reflector are subsequently embedded in the material of the plastic layers by lamination.

5. Method according to claim 1, characterized in that the reflector is attached to the outer side of the back cover of the solar cell module.

6. Method according to claim 3, characterized in that the back cover is provided as rear-side glass.

7. Method according to claim 3, characterized in that the reflector is attached to the back cover in the form of an imprint, an adhesive tape or an adhesive film.

8. Method according to claim 1, characterized in that the reflector is provided or configured linear or grid-shaped.

9. Method according to claim 1, characterized in that the reflector is attached to the rear-side of a rear-side glass of the solar cell module, wherein the rear-side glass is partially surface-treated for attaching the reflector.

10. Method according to claim 9, characterized in that the rear-side glass is coated with a metal for attaching the reflector.

11. Method according to claim 9, characterized in that the rear-side glass is etched or irradiated or ground for attaching the reflector.

12. Method according to claim 9, characterized in that a grid-shaped structure of the reflector is attached to the rear-side glass during the surface treatment by means of a grid-mask or without mask with a controlled nozzle.

13. Solar cell module, particularly manufactured in accordance with a method according to one of the preceding claims, having at least two adjoining bifacial solar cells, wherein a gap is provided between the solar cells and a diffuse reflector with flat surface is disposed and configured in the gap area such that it diffusely reflects light incident in the gap and a portion of the diffusely reflected light strikes on the solar cells through total reflection on a front boundary layer of the solar cell module.

14. Solar cell module according to claim 13, characterized in that the diffuse reflector includes an adhesive tape or an adhesive film with a pigment coating and with an adhesive layer.

15. Solar cell module according to claim 13, characterized in that the diffuse reflector comprises an imprint or an adhesive or a baking varnish, which contains white particle.

16. Solar cell module according to claim 13, characterized in that the diffuse reflector is partially formed with a surface treated back cover of the solar cell module.

17. Solar cell module according to claim 13, characterized in that the diffuse reflector is partially formed with a surface treated rear-side plastic layer of the solar cell module.
